(19) United States
(12) Patent Application Publication
(10) Pub. No.: US 2019/0280208 A1
(43) Pub. Date: Sep. 12, 2019

(54) BONDING METHOD AND COATING DEVICE

(71) Applicant: Sharp Kabushiki Kaisha, Sakai City, Osaka (JP)

(72) Inventors: Katsuhiro YAMAGUCHI, Sakai City (JP); Tadashi NISHIOKA, Sakai City (JP)

(21) Appl. No.: 16/463,010

(22) PCT Filed: Jul. 27, 2017
(86) PCT No.: PCT/JP2017/027215

§ 371 Date: May 22, 2019

(51) Int. Cl. H01L 51/00; B29C 63/02; B32B 37/16; B32B 37/00; H01L 27/32; H01L 51/56

(52) U.S. Cl. CPC H01L 51/0024; B29C 63/024; B32B 37/16; B32B 37/0053; B32B 2457/206; H01L 51/56; B32B 2307/412; B32B 2309/16; B32B 2315/08; H01L 27/32

(57) ABSTRACT

A base member is placed on a stage, and bonding is performed by bringing the base member and a film into pressure contact with each other with the stage and a roller. Then, the stage moves to perform the pressure contact throughout a whole area of the film.

### TECHNICAL FIELD

The disclosure relates to a manufacturing method for a display device such as an electroluminescence element (EL) device including an EL element.

### BACKGROUND ART

When a flexible EL device including an EL element is manufactured, various bonding such as that between a cover glass and an adhesive sheet needs to be performed.

### CITATION LIST

### Patent Literature

PTL 1: JP 2016-179600 A (Publication date: Oct. 13, 2016)
PTL 2: JP 2016-42121 A (Publication date: Mar. 31, 2016)

### SUMMARY

### Technical Problem

An object of the disclosure is to perform bonding favorably on a base member having a curved surface.

### Solution to Problem

A bonding method according to an aspect of the disclosure is a bonding method for bonding a film to a base member having a curved surface. The bonding method includes performing the bonding by bringing the base member placed on a stage and the film into pressure contact with each other with the stage and a roller, and moving the stage to perform the pressure contact throughout a whole area of the film.

### Advantageous Effects of Disclosure

According to the aspect of the disclosure, bonding of a base member having a curved surface can be favorably performed with a simple configuration.

### BRIEF DESCRIPTION OF DRAWINGS

FIG. 1 is a flowchart illustrating an example of a manufacturing method for an EL device.

FIG. 2A is a cross-sectional view illustrating a configuration example during a step of manufacturing an EL device of the present embodiment. FIG. 2B is a cross-sectional view illustrating a configuration example of an EL device of the present embodiment.

FIG. 3 is a drawing schematically illustrating a bonding device that performs bonding using a roller.

FIG. 4 is a drawing illustrating a portion of a stage of the bonding device.

FIGS. 5A and 5B are drawings each illustrating a portion of a stage of a bonding device.

FIGS. 6A to 6C are drawings each illustrating a motion of a stage of a bonding device.

FIG. 7 is a drawing illustrating a portion of a stage of a bonding device.

FIGS. 8A and 8B are drawings each schematically illustrating a coating device.

FIG. 8A illustrates a coating device during coating, and FIG. 8B illustrates the coating device after the coating.

FIG. 9 is a drawing schematically illustrating a coating device.

FIGS. 10A and 10B are drawings each schematically illustrating a coating device.

FIG. 10A illustrates a coating device during coating, and FIG. 10B illustrates the coating device after the coating.

FIGS. 11A and 11B are drawings each schematically illustrating a coating device. FIG. 11A illustrates a coating device during coating, and FIG. 11B illustrates the coating device after the coating.

### DESCRIPTION OF EMBODIMENTS

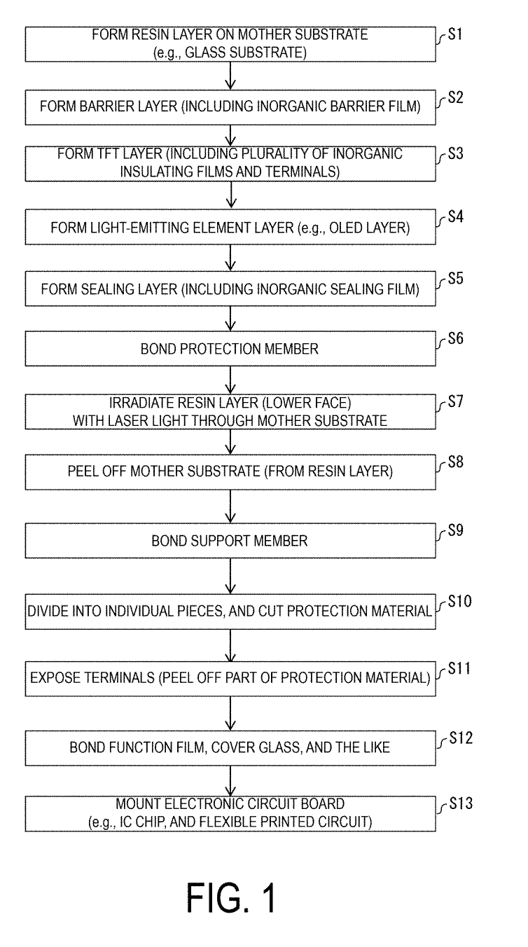

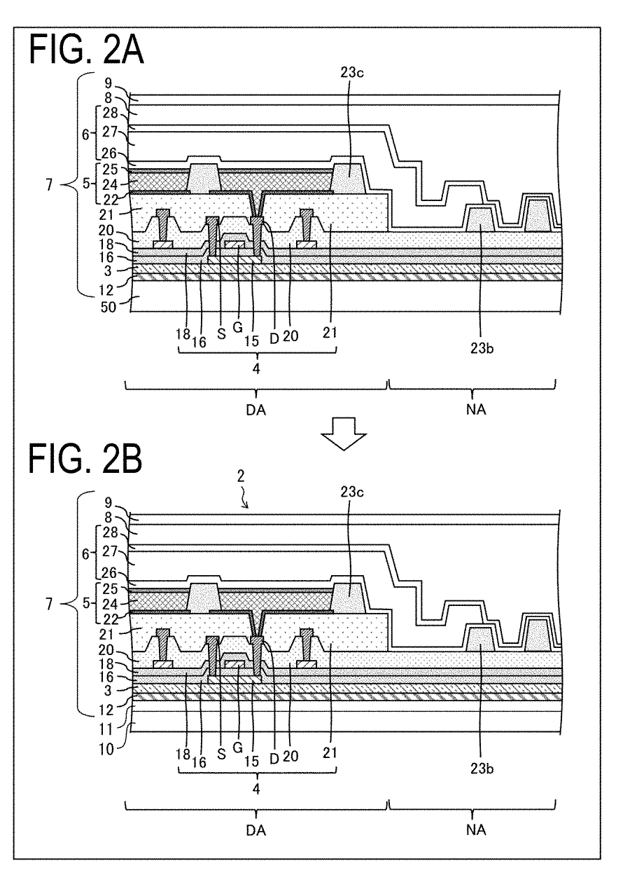

FIG. 1 is a flowchart illustrating an example of the manufacturing method for an EL device. FIG. 2A is a cross-sectional view illustrating a configuration example during a step of manufacturing an EL device of the present embodiment. FIG. 2B is a cross-sectional view illustrating a configuration example of the EL device of the present embodiment.

When a flexible EL device is manufactured, a resin layer 12 is first formed on a transparent mother substrate (e.g., a glass substrate) 50 (step S1), as illustrated in FIGS. 1, 2A, and 2B. Next, an inorganic barrier film 3 is formed (step S2). Subsequently, a TFT layer 4 is formed, the TFT layer 4 including a plurality of inorganic insulating films 16, 18, and 20, and a flattening film 21 (step S3). Next, a light-emitting element layer (e.g., an OLED element layer (display)) 5 is formed (step S4). Subsequently, a sealing layer 6 is formed, the sealing layer 6 including inorganic sealing films 26 and 28, and an organic sealing film 27 (step S5). Next, a protection member 9 (a PET film, for example) is bonded to the sealing layer 6, with an adhesive layer 8 interposed therebetween (step S6).

Subsequently, the resin layer 12 is irradiated with a laser (step S7). Here, the resin layer 12 absorbs the emitted laser to cause a lower face of the resin layer 12 (an interface with the mother substrate 50) to change in properties due to ablation. This forms a peeling layer 13 to deteriorate a bonding force between the resin layer 12 and the mother substrate 50. Next, the mother substrate 50 is peeled from the resin layer 12 (step S8). This causes the mother substrate 50 to be peeled from a layered body 7 illustrated in FIG. 2A.

Next, as illustrated in FIG. 2B, a support material 10 (e.g., a PET film) is bonded to the lower face of the resin layer 12 with an adhesive layer 11 interposed therebetween (step S9). Subsequently, the mother substrate 50 is divided while the protection member 9 is cut, so that a plurality of EL devices are cut (step S10). Next, the protection member 9 on a terminal portion of the TFT layer 4 is peeled off, and terminal exposure is performed (step S11). As a result, an EL device 2 illustrated in FIG. 2B is obtained. Then, a function film 39 is bonded (step S12), and an electronic circuit board is mounted on the terminal portion using an ACF or the like (step S13). Note that step S12 is not limited to bonding of the function film 39, and widely includes bonding between the layered body 7 and another component, such as bonding of a cover glass, for example. Each of the steps above is performed by a manufacturing apparatus of an EL device.

A manufacturing method for an EL device, according to an aspect of the disclosure, particularly has features of step S12. Details thereof will be described below.

Examples of the material of the resin layer 12 include polymide, epoxy, and polyamide. Among them, polyimide is suitably used.

The inorganic barrier film 3 is configured to prevent water or impurities from reaching the TFT layer 4 or the light-emitting element layer 5, and may be made of a silicon oxide film, a silicon nitride film, or a silicon oxynitride film, formed with CVD, or a layered film thereof, for example. The inorganic barrier layer 3 has a thickness from 50 nm to 1500 nm, for example.

The TFT layer 4 includes a semiconductor film 15, the inorganic insulating film 16 (gate insulating film) formed on an upper side of the semiconductor film 15, a gate electrode G formed on an upper side of the gate insulating film 16, the inorganic insulating films 18 and 20 formed on an upper side of the gate electrode G, a source electrode S, a drain electrode D, and a terminal TM, formed on an upper side of the inorganic insulating film 20, and the flattening film 21 formed on an upper side of each of the source electrode S and the drain electrode D. The semiconductor film 15, the inorganic insulating film 16, the gate electrode G, the inorganic insulating films 18 and 20, the source electrode S, and the drain electrode D constitute a thin film transistor (TFT). The TFT layer 4 is provided in its end portion (non-active region NA) with a plurality of terminals TM used for connection with an IC chip and an electronic circuit board such as a FPC and a terminal portion including a terminal wiring line TW. Each of the terminals TM is electrically connected to the corresponding one of various wiring lines of the TFT layer 4 with the terminal wiring line TW therebetween.

The semiconductor film 15 is made of a low-temperature polysilicon (LTPS) or an oxide semiconductor, for example. The gate insulating film 16 can be formed of, for example, a silicon oxide (SiOx) film, a silicon nitride (SiNx) film, or a layered film thereof formed using a CVD method. The gate electrode G, the source electrode S, the drain electrode D, and the terminal are formed of a metal single layer film or a layered film including, for example, at least one of aluminum (Al), tungsten (W), molybdenum (Mo), tantalum (Ta), chromium (Cr), titanium (Ti), or copper (Cu). Note that, in FIGS. 2A and 2B, the TFT is illustrated that has a top gate structure in which the semiconductor film 15 functions as the channel, but the TFT may have a bottom gate structure (when the channel of the TFT is formed in the oxide semiconductor, for example).

The inorganic insulating films 18 and 20 can be constituted by a silicon oxide (SiOx) film or a silicon nitride (SiNx) film, or a layered film of these, formed using CVD. The flattening film 21 is an organic insulating film that can be made of a coatable photosensitive organic material such as polymide, or acrylic, for example.

The light-emitting element layer 5 (e.g., an organic light emitting diode layer) includes an anode electrode 22 formed on an upper side of the flattening film 21, a partition 23c that defines a subpixel of an active region DA, a bank 23b formed in the non-active region NA, an electroluminescence (EL) layer 24 formed on the anode electrode 22, and a cathode electrode 25 formed on an upper side of the EL layer 24, and the anode electrode 22, the EL layer 24, and the cathode electrode 25 constitute a light-emitting element (e.g., an organic light emitting diode).

The partition 23c and the bank 23b may be formed in the same step, for example, using a coatable photosensitive organic material such as polyimide, epoxy, or acrylic. The bank 23b of the non-active region NA is formed on the inorganic insulating film 20. The bank 23b defines the edge of the organic sealing film 27.

The EL layer 24 is formed by vapor deposition or an ink-jet method in a region (subpixel region) enclosed by the partition 23c. In a case that the light-emitting element layer 5 is an organic light emitting diode (OLED) layer, for example, the EL layer 24 is formed by layering a hole injecting layer, a hole transport layer, a light emitting layer, an electron transport layer, and an electron injecting layer from the lower layer side.

The anode electrode (anode) 22 is composed of a layer made of an alloy containing Indium Tin Oxide (ITO) and Ag and has light reflectivity. The cathode electrode 25 may be made of a transparent metal such as Indium Tin Oxide (ITO) or Indium Zinc Oxide (IZO).

In a case that the light-emitting element layer 5 is the OLED layer, positive holes and electrons are recombined inside the EL layer 24 by a drive current between the anode electrode 22 and the cathode electrode 25, and light is emitted as a result of excitons that are generated by the recombination falling into a ground state.

The light-emitting element layer 5 is not limited to OLED element configurations and may be an inorganic light emitting diode or a quantum dot light emitting diode.

The sealing layer 6 includes a first inorganic sealing film 26 covering the partition 23c and the cathode electrode 25, an organic sealing film 27 covering the first inorganic sealing film 26, and a second inorganic sealing film 28 covering the organic sealing film 27.

The first inorganic sealing film 26 and the second inorganic sealing film 28 can be each constituted by a silicon oxide film, a silicon nitride film, or a silicon oxynitride film, or by a layered film of these, formed using CVD. The organic sealing film 27 is a transparent organic insulating film that is thicker than the first inorganic sealing film 26 and the second inorganic sealing film 28, and may be formed of a coatable photosensitive organic material such as polymide or acrylic. For example, after coating the first inorganic sealing film 26 with an ink containing such an organic material using the ink-jet method, the ink is cured by UV irradiation. The sealing layer 6 covers the light-emitting element layer 5 and inhibits foreign matter, such as water and oxygen, from infiltrating to the light-emitting element layer 5.

The protection member 9 is bonded to the sealing layer 6 with the adhesive layer 8 interposed therebetween and functions as a support member when the mother substrate 50 is peeled off. Examples of a material of the protection member 9 include polyethylene terephthalate (PET).

After the mother substrate 50 has been peeled off, the support member 10 is bonded to the lower face of the resin layer 12 so as to manufacture an EL device having excellent flexibility. Examples of a material of the support member 10 include polyethylene terephthalate (PET).

The function film has an optical compensation function, a touch sensor function, a protective function, and the like, for example.

The electronic circuit board is an IC chip or a flexible printed circuit board that is mounted on a plurality of terminals TM, for example.

### Step 12

Hereinafter, step 12 (bonding of a function film, a cover glass, and the like), which is a feature of the disclosure, will be described.

Here, there is a plurality of conceivable configurations and methods for the bonding and bonding associated therewith. For example, conceivable bonding of a combination is as follows: (1) bonding between the layered body 7 and the cover glass; (2) bonding between the layered body 7 and the function film; and (3) bonding between the layered body 7 and an integrated part of the function film and the cover glass. Previous processes of these kinds of bonding also include bonding between the cover glass and the function film and bonding between the cover glass and the adhesive layer. The layered body 7 is subjected to the bonding as needed after the adhesive layer 8 and the protection member 9 are removed from the layered body 7.

In addition, a method for bonding may include a bonding method performed under a vacuum or a bonding method performed under an atmosphere, for example. The bonding includes a case of directly bonding a layered body to a cover glass or a function film and a case of bonding a layered body to an integrated part formed by bonding a function film to a cover glass.

### First Embodiment

### Roller Movement

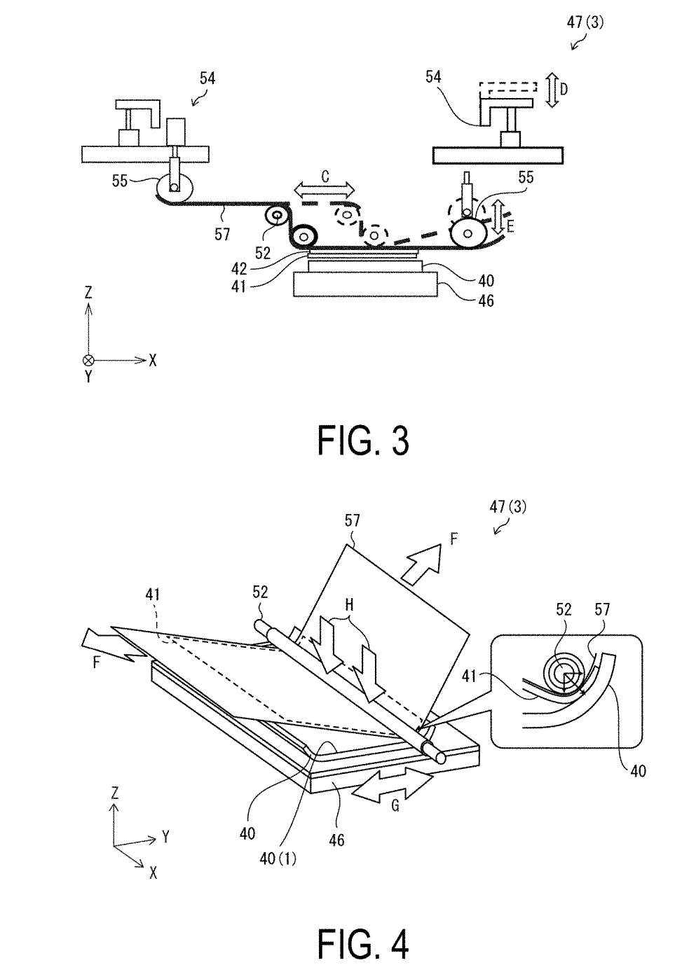

In a first embodiment, a case of bonding between a film such as an optical clear adhesive (OCA) 41 and a cover glass 40 will be described with reference to FIG. 3 and the like. FIG. 3 is a drawing schematically illustrating a bonding device 47(3) that performs the bonding using a roller 52.

As illustrated in FIG. 3, the bonding device 47(3) includes a stage 46, a roller 52, a carrier tape 57, and tension control devices 54. The tension control devices 54 are provided on both sides of the stage 46, and each include a tension roller 55. The roller 52 is provided to be movable above the stage 46. The carrier tape 57 is fed through the two tension rollers 55 and the roller 52 provided therebetween, and is subjected to tension by operation of the tension control device 54. Specifically, each of the tension control devices 54 is provided to be movable in a vertical direction (Z-axis direction), and each of the tension rollers 55 also moves up and down (arrow E in FIG. 3) in accordance with vertical movement (arrow D in FIG. 3) of the corresponding one of the tension control devices 54. This applies tension to the carrier tape 57 and controls the tension. The cover glass 40 is placed on the stage 46, and the carrier tape 57 holds the OCA 41 with an adhesive sheet 42 interposed therebetween. The adhesive sheet 42 is configured to hold a film such as the OCA 41 to the carrier tape 57 with slight adhesion, and is also called an Adhesive Sheet (AS (holding sheet)).

On the stage 46, the cover glass 40, the OCA 41, the adhesive sheet 42, and the carrier tape 57 are disposed in this order from the stage 46. The roller 52 then moves from one end of the stage 46 to the other end thereof (arrow C in FIG. 3) while pressing the OCA 41 on the cover glass 40 with the carrier tape 57 interposed therebetween. As a result, the OCA 41 is bonded to the cover glass 40. At this time, the adhesive sheet remains adhered to the carrier tape 57, and only the OCA 41 is bonded to the cover glass 40.

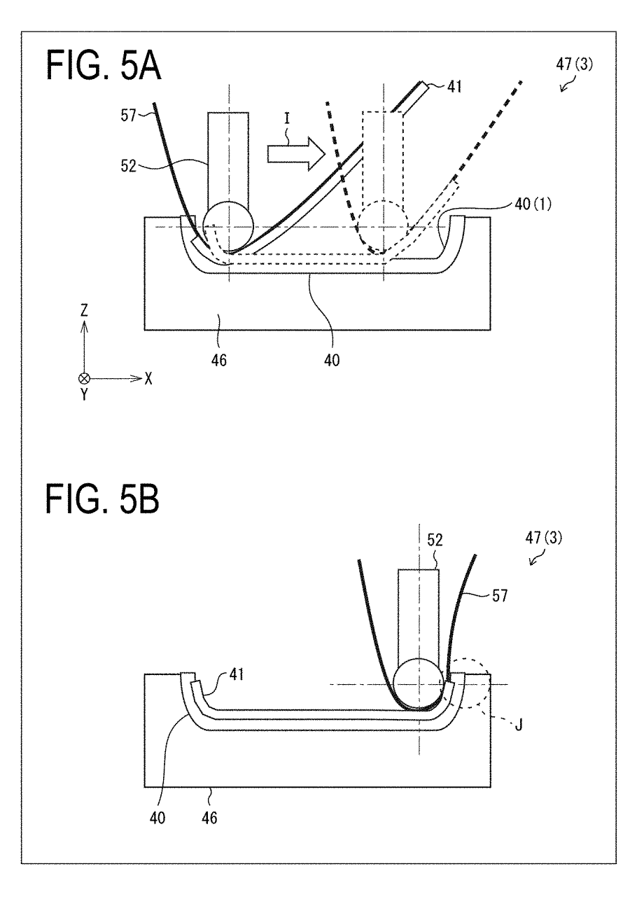

With reference to FIGS. 4, 5A, and 5B, details of the embodiment will be described. FIGS. 4, 5A, and 5B each illustrate a portion of the stage 46 of the bonding device 47(3). As illustrated in FIG. 4, the roller 52 applies pressure on an inner surface 40(1) of the cover glass 40 in a substantially vertical direction (arrow H in FIG. 4). Then, the roller 52 moves in a direction (arrow G in FIG. 4 (X-axis direction)) parallel to an upper face of the stage 46. The carrier tape 57 is then subjected to tension upward (Z-axis direction), or in a direction along a curved direction of the inner surface 40(1), to which the OCA 41 is to be bonded, of the cover glass 40 (arrow F in FIG. 4).

To perform positioning or the like, the stage 46 may be configured to be rotatable in XY-plane, for example.

As illustrated in FIG. 5A, when the roller 52 has a diameter corresponding to a radius of a curve of an end portion of the cover glass 40, this favorably facilitates the bonding between the OCA 41 and the cover glass 40. However, as illustrated in FIG. 5B, after the roller 52 moves forward (arrow I in FIG. 5A), the roller 52 may be less likely to apply tension on the carrier tape 57 in a curved portion in the end portion of the cover glass 40 (portion J surrounded by a dotted line in FIG. 5B). This is because the carrier tape 57 may be caught in the end portion of the cover glass 40. Such a case may cause failure of bonding.

### Stage Movement

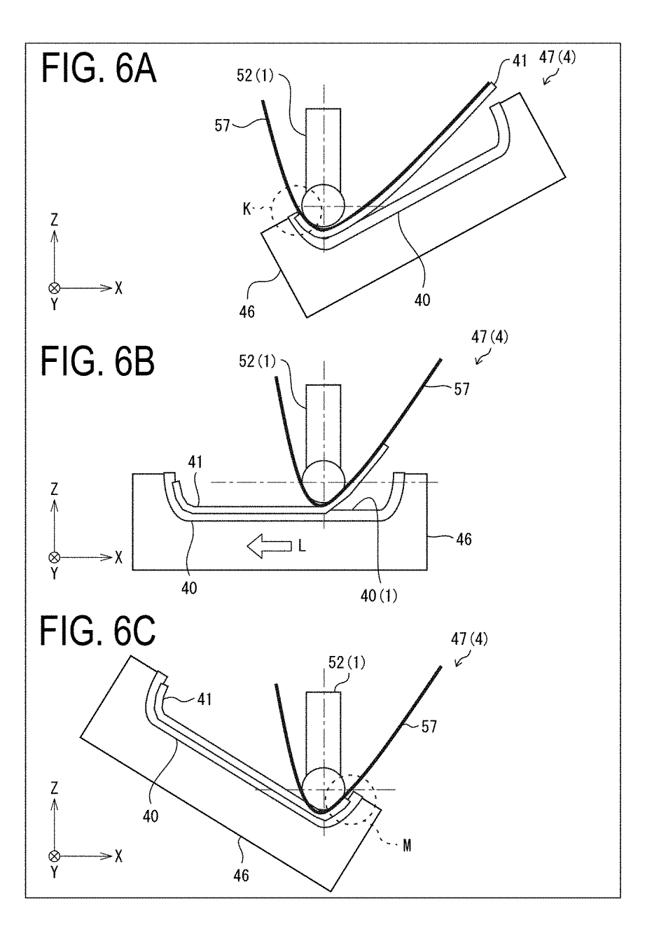

There is a conceivable configuration in which a stage with a roller fixed is moved instead of the configuration in which the roller 52 is moved while the stage 46 is fixed as illustrated in FIGS. 5A and 5B. Stage movement will be described with reference to FIGS. 6A to 6C.

FIGS. 6A to 6C are drawings each illustrating a motion of the stage 46 of the bonding device 47(4). In order of FIGS. 6A, 6B, and 6C, bonding progresses. From FIG. 6A to FIG. 6C, a roller 52(1) is fixed in X-axis direction. Then, the stage 46 moves while changing its inclination angle. Specifically, the stage 46 moves in X-axis direction while changing its inclination in Z-axis direction.

FIG. 6A schematically illustrates the bonding device 47(4) at the time of starting bonding. As illustrated in FIG. 6A, the other end of the stage 46, or an end portion in which the roller 52(1) is not positioned, inclines upward (in +Z-axis direction). This causes the carrier tape 57 to be less likely to be caught by the end portion of the cover glass 40 (portion K surrounded by a dotted line in FIG. 6A).

While the OCA 41 is bonded to a planar portion of the cover glass 40, the stage 46 returns to a state in which an angle thereof is parallel to X-axis (no inclination) as illustrated in FIG. 6B, and then moves in a direction (−X-axis direction) indicated by arrow L in FIG. 6B. This enables the roller 52(1) to be pressed on the planar portion of the cover glass 40 in a direction substantially perpendicular to the inner surface 40(1) (X-axis direction), to which the OCA 41 is to be bonded, of the cover glass 40. As a result, favorable bonding can be performed in the planar portion of the cover glass 40.

FIG. 6C schematically illustrates the bonding device 47(4) at the time of finishing bonding. As illustrated in FIG. 6C, the other end of the stage 46, or the end portion in which the roller 52(1) is not positioned, inclines upward (+Z-axis direction). The stage 46 moves, so that the stage 46 illustrated in FIG. 6C inclines in a direction opposite to that of the stage 46 illustrated in FIG. 6A. This causes the carrier tape 57 to be less likely to be caught by the end portion of the cover glass 40 (portion M surrounded by a dotted line in FIG. 6C), so that bonding failure can be suppressed. Note that an inclination direction of the stage 46 is preferably set such that a direction of pressure to be applied to the cover glass 40 by the roller 52(1) comes close to a direction of a normal to a curved surface of the cover glass 40. This enables a difference in bonding condition between the planar portion and the curved surface to be reduced.

Rotational speed of the roller 52(1) and pressure applied to the cover glass 40 or the like by the roller 52(1) (pressure at the time when the cover glass 40 and the OCA 41 are brought into pressure contact with each other using the stage 46 and the roller 52(1)) at the time of bonding are not particularly limited to a specific speed and pressure, and are appropriately determined in accordance with physical properties or the like of a component to be bonded and a bonding component. The roller 52(1) is fixed in X-axis direction at least during bonding, but is movable in Z-axis direction so that the pressure or the like thereof can be adjusted. For example, when the cover glass 40 is a component to be bonded and the OCA 41 is a bonding component, bonding starts while the roller 52(1) is being rotated (the roller 52(1), the carrier tape 57, the OCA 41, and the cover glass 40 comes into contact with each other), and the roller 52(1) rotates while a load (5 kgf/cm²) is maintained evenly. In and near a curved end portion of the cover glass 40, the load may be changed to 10 kg/cm². To change and control a load, the roller 52(1) is moved up and down in Z-axis direction. When the stage 46 is inclined, a large load may be applied to an inclined face thereof.

Magnitude of the load is set lower when a component to be bonded and a bonding component are each a layered body including a light-emitting element layer, for example. This is because the light-emitting element layer needs to be prevented from having a defect.

When the stage 46 is configured to be movable as described above, the bonding device 47(4) can have a simple structure. In addition, bonding can be performed while finely following a minimal curved surface with a small curve's diameter of the cover glass 40. Further, a bonding face is likely to be pressed uniformly, so that bubbles are less likely to be trapped, and a non-defective part can be easily obtained.

In the description above, a case in which the OCA 41 is bonded to the cover glass 40 is described, for example. However, a bonding component is not limited thereto, and a layered body including a light-emitting element layer, a function film such as a Touch Screen Panel (TSP) (a touch panel), and the like may be used instead of the cover glass, for example. In addition, a polarizing film (POL) may be used instead of the OCA.

The bonding described above can be performed both under a vacuum and under an atmosphere. However, performing under a vacuum causes bubbles to be less likely to enter a bonding face as compared with that under an atmosphere.

While a position of a rotation axis of the stage 46 at the time when the stage 46 inclines in Z-axis direction is not particularly limited to a specific position, the position can be set at the center of the stage 46 in X-axis direction, or at an end portion of the stage 46, or in or near a portion where a curved face is provided in the stage 46, for example.

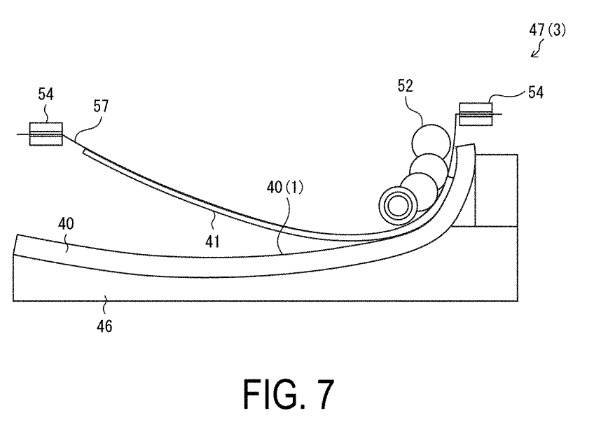

In addition, when the roller 52 has a diameter less than a radius of a curve of the cover glass 40 as illustrated in FIG. 7, more favorable bonding can be performed.

### Second Embodiment

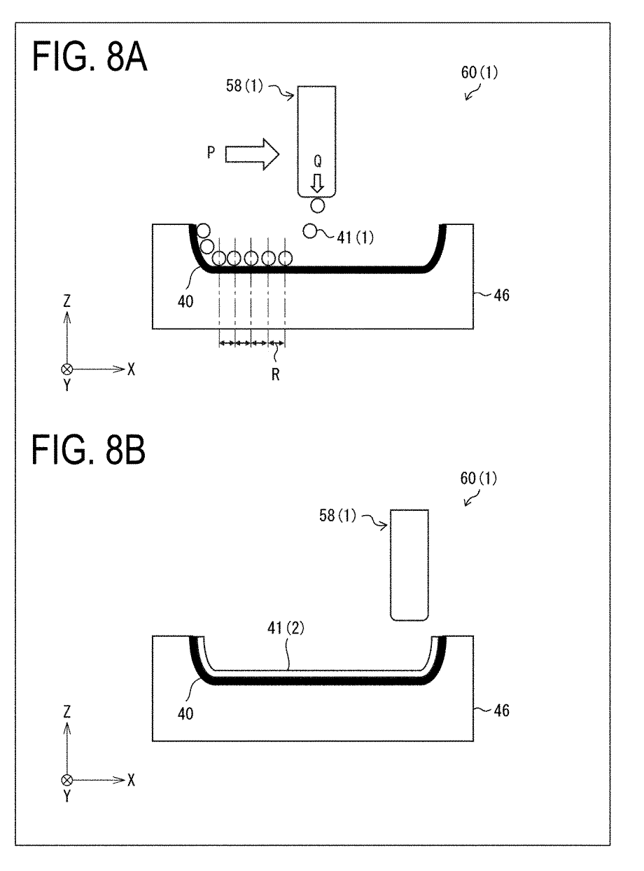

A second embodiment will be described for applying a liquid adhesive to a cover glass 40 instead of using a film-like OCA that is preliminarily formed into a film as an adhesive 41 with reference to FIGS. 8A and 8B. FIGS. 8A and 8B are drawings each schematically illustrating a coating device 60(1) of the present embodiment. FIG. 8A illustrates the coating device during coating, and FIG. 8B illustrates the coating device after the coating.

The coating device 60(1) includes a stage 46 and a coating machine 58(1). On the stage 46, a cover glass 40 is disposed, and the coating machine 58(1) is disposed above the cover glass 40. The coating machine 58(1) is configured to be able to eject a liquid adhesive such as a liquid OCR resin. In the present embodiment, the coating machine 58(1) ejects particles of OCR resin (resin particles 41(1)) onto the cover glass 40 from above the cover glass 40 (arrow Q in FIG. 8A, or −Z-axis direction).

The coating machine 58(1) moves above the cover glass 40 in a direction (arrow P in FIG. 8A, or X-axis direction) parallel to a planar section of the cover glass 40. This enables the single coating machine 58(1) to apply the resin particles 41(1) to whole area of the cover glass 40.

Movement of the coating machine 58(1) is controlled so as to cause the resin particles 41(1) on the cover glass 40 to have a uniform thickness. For example, the resin particles 41(1) are applied to the planar section of the cover glass 40 at equal intervals, as indicated by arrow R in FIG. 8A.

When the coating machine 58(1) includes a plurality of ejection ports provided in a direction (Y axial direction) orthogonal to a movement direction (arrow P) of the coating machine 58(1), for example, the resin particles 41 can be applied to the cover glass 40 across a full width in Y-axial direction by one ejection (line coating). This enables the coating machine 58(1) to apply the resin particles 41 to a whole area of the cover glass 40 by once moving the coating machine 58(1) throughout the full width of the cover glass 40 in X-axis direction (one scanning).

The configuration of the coating machine 58(1) is not particularly limited to a specific configuration, and examples thereof include various coating machines for jet coating, such as a piezo-jet type and a mechanical jet type, and for another coating, for example.

After coating, treatment such as heating is appropriately performed as needed to form a coating film of an adhesive on a surface of the cover glass 40. FIG. 8B illustrates a state where the resin particles 41(1) applied form a resin layer 41(2). The resin layer 41(2) has a function similar to that of the OCA 41 formed by bonding (lamination) a film (tape).

That is, the resin layer 41(2) interposed between a function film and the cover glass 40 allows the function film such as a polarizing film (POL) to be bonded to the cover glass 40.

For the bonding, the bonding method can be used in which the stage moves while the roller is fixed, such as described in the first embodiment with reference to FIGS. 6A to 6C.

Forming an adhesive layer with coating enables an adhesive layer to be formed on a surface of a cover glass without being restricted by a shape of the cover glass. Specifically, a favorable adhesive layer can be formed on a surface of not only a cover glass having a 2.5D shape but also a cover glass having a 3.0D shape, for example.

### Third Embodiment

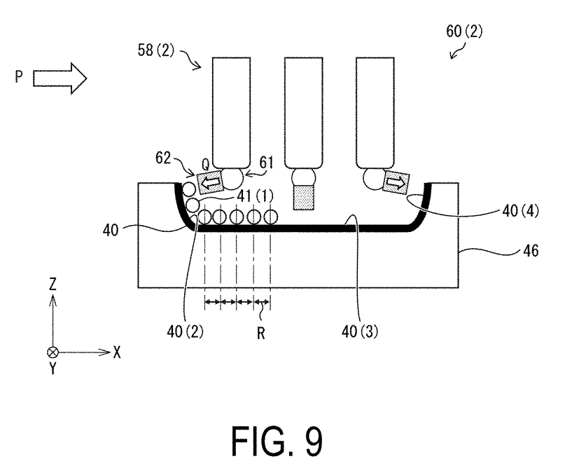

In a third embodiment, another configuration will be described in which a liquid adhesive is applied to a cover glass 40 with reference to FIG. 9. FIG. 9 is a drawing schematically illustrating a coating device 60(2). The coating device 60(2) of the present embodiment is different from the coating device 60(1) of the second embodiment illustrated in FIG. 8A in a mode of applying resin particles 41 to the cover glass 40. Specifically, a coating machine provided in each of the coating device has a different configuration.

A coating machine 58(2) of the present embodiments is provided at its leading end portion with an ink supplying unit 61 and a head 62. For details, the head 62 is provided in the ink supplying unit 61 in a movable manner. FIG. 9 exemplifies a configuration in which the ink supplying unit 61 has a spherical shape, and the head 62 is provided in the ink supplying unit 61 so as to be movable along an outer periphery of the ink supplying unit 61. This allows the head 62 to be rotatable in the leading end portion of the coating machine 58(2).

The head 62 is rotatable, and thus can be appropriately changed in angle in accordance with a positional relationship between the head 62 and the cover glass 40, for example. As a result, when the cover glass 40 has curbed opposite ends in X-axis direction as illustrated in FIG. 9, for example, an angle between an ejection direction (arrow Q in FIG. 9) of the resin particles 41(1) and a surface of the cover glass 40 can be easily maintained at or near 90 degrees.

Specifically, the head 62 operates as follows, for example. When the coating machine 58(2) moves from a side in −X-axis direction to a side in +X-axis direction (arrow P in FIG. 9), an inclination direction of the head 62 changes in order as follows: −X-axis direction; −Z-axis direction (vertical direction); and +X-axis direction, with movement of the coating machine 58(2).

As a result, when the resin particles 41(1) are ejected onto a vertical face on a side in −X-axis direction (first vertical face 40(2)) of the cover glass 40, the head 62 is inclined in −X-axis direction to enable the resin particles 41(1) to be ejected onto the cover glass 40 from a direction at or near 90 degrees from the cover glass 40. When the coating machine 58(2) moves in a direction of arrow P to start reaching a planar face 40(3), the head 62 turns in −Z-axis direction (vertical direction). Subsequently, when the coating machine 58(2) starts reaching a vertical face on a side in +X-axis direction (second vertical face 40(4)) of the cover glass 40, the head 62 inclines in +X-axis direction.

The head 62 rotates along the curved surface of the cover glass 40 as described above. This enables the resin particles 41(1) to be ejected onto the cover glass 40 while an angle between an ejection direction of the resin particles 41(1) (arrow Q in FIG. 9) and the curved surface of the cover glass 40 is maintained at substantially 90 degrees.

Therefore, the resin particles 41(1) can be uniformly ejected throughout a whole area of the cover glass 40, so that forming of a uniform OCA resin layer 41(2) is facilitated.

### Fourth Embodiment

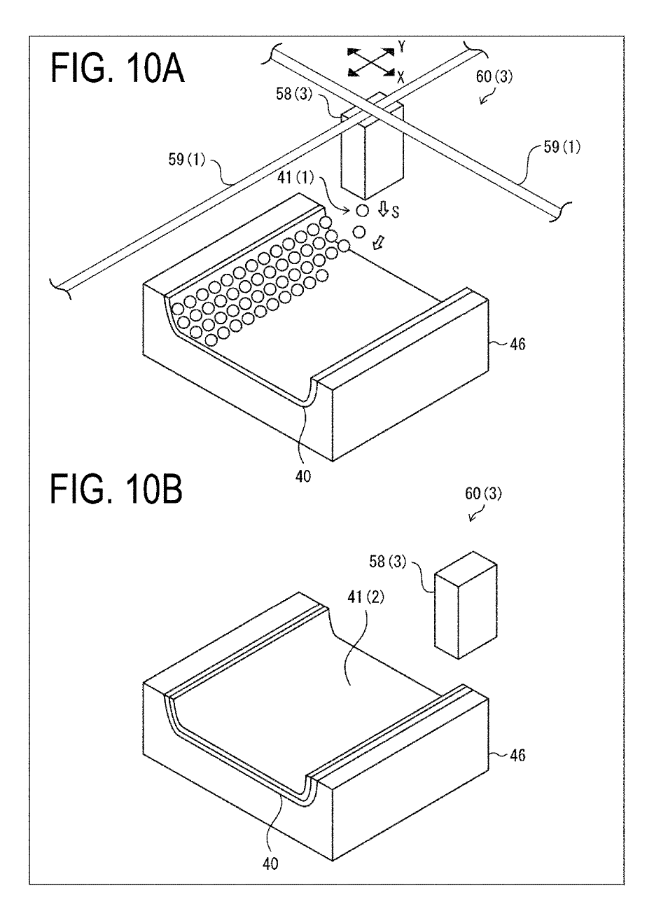

In a fourth embodiment, another configuration will be described in which a liquid adhesive is applied to the cover glass 40 with reference to FIGS. 10A and 10B. FIGS. 10A and 10B are drawings each schematically illustrating a coating device 60(3) of the present embodiment. FIG. 10A illustrates the coating device during coating, and FIG. 10B illustrates the coating device after the coating. The fourth embodiment is different from the second embodiment in that a coating machine 58(3) includes an XY-axis drive mechanism 59(1).

When the coating machine 58(3) is movable in X-axis direction and Y-axis direction as illustrated in FIG. 10A, even the coating machine 58(3) including only one ejection port, for example, enables resin particles 41(1) to be applied to a whole area of a surface of the cover glass 40 by ejecting the resin particles 41(1) (arrow S in FIG. 10A) while the coating machine 58(3) is moved in X-axis direction and Y-axis direction (two directions orthogonal to each other).

This enables the coating machine 58(3) to have a simple configuration in which the number of ejection ports of the coating machine 58(3) is set to one, for example.

Note that a configuration of the XY-axis drive mechanism is not particularly limited to a specific configuration. For example, an XY-movable mechanism may be provided above the coating machine 58(3), and the coating machine 58(3) may be installed in the XY-movable mechanism.

### Fifth Embodiment

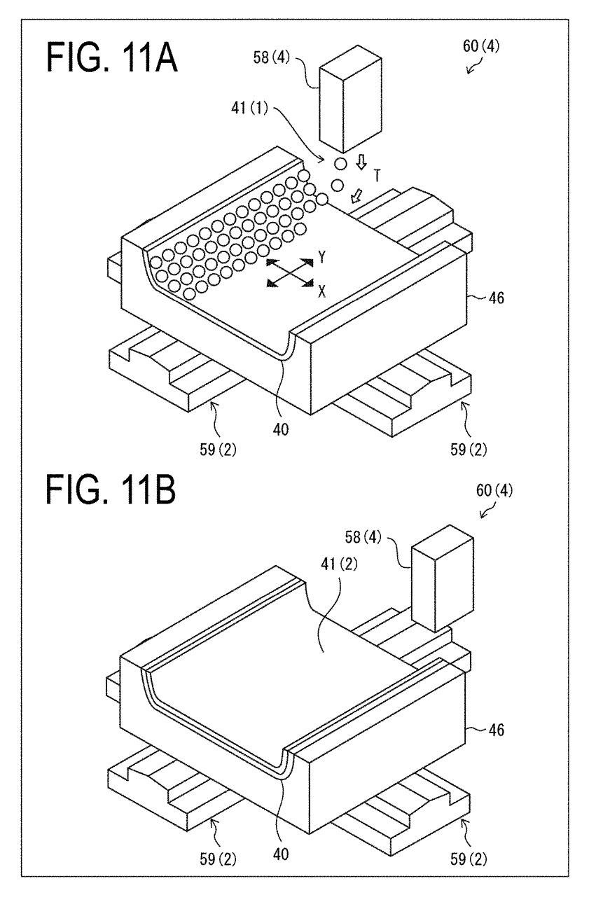

In a fifth embodiment, another configuration will be described in which a liquid adhesive is applied to the cover glass 40 with reference to FIGS. 11A and 11B. FIGS. 11A and 11B are drawings each schematically illustrating a coating device 60(4) of the present embodiment. FIG. 11A illustrates the coating device during coating, and FIG. 11B illustrates the coating device after the coating. The fifth embodiment is different from the second embodiment in that the stage 46 includes an XY-axis drive mechanism 59(2).

When the stage 46 is movable in X-axis direction and Y-axis direction as illustrated in FIG. 11A, even the coating machine 58(4) including only one ejection port and fixed, for example, enables resin particles 41(1) to be applied to a whole area of a surface of the cover glass 40 by ejecting the resin particles 41(1) from the coating machine 58(4) (arrow T in FIG. 11A) while the stage 46 is moved in X-axis direction and Y-axis direction (two directions orthogonal to each other).

This enables the coating machine 58(4) to have a simple configuration in which the number of ejection ports of the coating machine 58(4) is set to one, for example.

Note that a configuration of the XY-axis drive mechanism is not particularly limited to a specific configuration. For example, an XY-movable mechanism may be provided below the stage 46, and the stage 46 may be installed in the XY-movable mechanism.

### Supplement

A bonding method according to a first aspect of the disclosure is a bonding method for bonding a film and a base member having a curved surface. The bonding method includes performing the bonding by bringing the base member placed on a stage and the film into pressure contact with each other with the stage and a roller, and moving the stage to perform the pressure contact throughout a whole area of the film.

According to the bonding method of a second aspect of the disclosure, the stage inclines along the curved surface.

According to the bonding method of a third aspect of the disclosure, the stage inclines to cause a direction of the pressure contact to come close to a direction of a normal to the curved surface.

According to the bonding method of a fourth aspect of the disclosure, the base member includes a cover glass of a display.

According to the bonding method of a fifth aspect of the disclosure, the film includes an adhesive film.

A bonding device according to a sixth aspect of the disclosure is a bonding device configured to perform bonding of a film to a base member. The bonding device includes a roller and a stage. The base member is placed on the stage. The base member and the film are brought into pressure contact with each other with the stage and the roller, and the bonding is performed. Then, the stage moves, and the pressure contact is performed throughout a whole area of the film.

A coating method according to a seventh aspect of the disclosure is a coating method for providing an adhesive layer on a base member having a curved surface. The coating method includes coating the base member placed on a state with resin particles to form the adhesive layer.

According to the coating method of an eighth aspect of the disclosure, the coating of the base member in one width direction can be performed at once, and the coating is performed forward in a direction orthogonal to the one width direction to provide the adhesive layer in a whole area of the base member.

According to the coating method of a ninth aspect of the disclosure, a position of the coating is variable in two directions orthogonal to each other on the base member.

According to the coating method of a tenth aspect of the disclosure, the stage is movable in two directions orthogonal to each other.

According to the coating method of an eleventh aspect of the disclosure, the coating is performed with a piezo-jet type or a mechanical jet type.

According to the coating method of a twelfth aspect of the disclosure, the base member includes a cover glass of a display.

A coating device according to a thirteenth aspect of the disclosure is a coating device configured to provide an adhesive layer on a base member. The coating device includes a stage and a coating machine. The base member is placed on the stage, and the coating machine is configured to eject resin particles onto the base member.

According to the coating device of a fourteenth aspect of the disclosure, the coating machine includes a head configured to eject the resin particles, and the head is configured to be rotatable.

According to the coating device of a fifteenth aspect of the disclosure, the head is configured to rotate along a curved surface of the base member.

According to the coating device of a sixteenth aspect of the disclosure, the coating machine includes an XY-axis drive mechanism and is configured to be movable in two directions orthogonal to each other above the base member.

According to the coating device of a seventeenth aspect of the disclosure, the stage includes an XY-axis drive mechanism and is configured to be movable in two directions orthogonal to each other above the base member.

According to the coating device of an eighteenth aspect of the disclosure, the coating machine includes a piezo-jet type or a mechanical jet type of coating machine.

### ADDITIONAL ITEMS

The disclosure is not limited to the embodiments described above. Embodiments obtained by appropriately combining technical approaches disclosed in the corresponding embodiments are also included within the technical scope of the disclosure. In addition, novel technical features may be formed by combining the technical approaches disclosed in the corresponding embodiments.

### REFERENCE SIGNS LIST

2 EL device
4 TFT layer
3 Inorganic barrier film
5 Light-emitting element layer (display)
6 Sealing layer
7 Layered body
8, 11 Adhesive layer
9 Protection member
10 Support member
12 Resin layer
13 Peeling layer
15 Semiconductor film
16 Gate insulating film
16, 18, 20 Inorganic insulating film
21 Flattening film
22 Anode electrode
23b Bank
23c Partition
24 EL layer
25 Cathode electrode
26 First inorganic sealing film
26, 28 Inorganic sealing film
27 Organic sealing film
28 Second inorganic sealing film
39 Function film
40 Cover glass (base member)
40(1) Inner surface (face to be bonded)
40(2) First vertical face
40(3) Planar face
40(4) Second vertical face
41 Adhesive layer (Optical Clear Adhesive (OCA), bonding component, adhesive film)
41(1) OCA resin particles
41(2) OCA resin layer
42 Adhesive sheet (Adhesive Sheet (AS), holding sheet)
46 Stage
47(1), (2), (3), (4) Bonding device
50 Mother substrate
52 Roller
52(1) Roller
54 Tension control device
55 Tension roller
57 Carrier tape
58(1), (2), (3), (4) Coating machine
59(1), (2) XY-axis drive mechanism
60(1), (2), (3), (4) Coating device
61 Ink supplying unit
62 Head
DA Active region
NA Non-active region

1. (canceled)

2. A bonding method for bonding a film to a base member having a curved surface, the bonding method comprising:
performing the bonding by bringing the base member placed on a stage and the film into pressure contact with each other with the stage and a roller; and
moving the stage to perform the pressure contact throughout a whole area of the film,
wherein the stage inclines along the curved surface.

3. The bonding method according to claim 2,
wherein the stage inclines to cause a direction of the pressure contact to come close to a direction of a normal to the curved surface.

4. The bonding method according to claim 2,
wherein the base member includes a cover glass of a display body.

5. The bonding method according to claim 2,
wherein the film includes an adhesive film.

6-13. (canceled)

14. A coating device configured to provide an adhesive layer on a base member, the coating device comprising:
a stage; and
a coating machine,
wherein the base member is placed on the stage,
the coating machine is configured to eject resin particles onto the base member, and the adhesive layer is provided,
the coating machine includes a head configured to eject the resin particles, and
the head is configured to be rotatable.

15. The coating device according to claim 14,
wherein the head is configured to rotate along a curved surface of the base member.

16. The coating device according to claim 14,
wherein the coating machine includes an XY-axis drive mechanism, and
the coating machine is configured to be movable in two directions orthogonal to each other above the base member.

17. The coating device according to claim 14,
wherein the stage includes an XY-axis drive mechanism, and
the stage is configured to be movable in two directions orthogonal to each other above the base member.

18. The coating device according to claim 14,
wherein the coating machine includes a piezo-jet type or a mechanical jet type of coating machine.
